(19) United States
(12) Patent Application Publication
(10) Pub. No.: US 2025/0369102 A1
(43) Pub. Date: Dec. 4, 2025

(54) LOWER K AND HIGHER HARDNESS WITH IMPROVED PLASMA INDUCED DAMAGE (PID) DIELECTRIC FILM DEPOSITION

(71) Applicant: Applied Materials, Inc., Santa Clara, CA (US)

(72) Inventors: Rui LU, Santa Clara, CA (US); Bo XIE, San Jose, CA (US); Chi-I LANG, Cupertino, CA (US); Li-Qun XIA, Santa Clara, CA (US); Shankar VENKATARAMAN, San Jose, CA (US)

(21) Appl. No.: 18/731,943

(22) Filed: Jun. 3, 2024

(51) Int. Cl. C23C 16/24; C23C 16/27; C23C 16/455

(52) U.S. Cl. CPC C23C 16/24; C23C 16/272; C23C 16/45502; C23C 16/45557

(57) ABSTRACT

In some embodiments, a method of forming a dielectric film includes exposing a substrate in a processing chamber to a silicon precursor having general Formula (I) to form a silicon-containing film on the substrate. Formula (I) can be represented by:

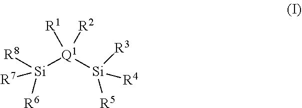

wherein Q¹ is a carbon atom or an oxygen atom, and each of R¹, R², R³, R⁴, R⁵, R⁶, R⁷, and R⁸ is independently selected from a hydrogen atom, a substituted alkyl, an unsubstituted alkyl, a substituted alkoxy, an unsubstituted alkoxy, a substituted vinyl, an unsubstituted vinyl, a silane, a substituted amine, an unsubstituted amine, or a halide. The method further includes purging the processing chamber of the silicon precursor.

### FIELD

The present disclosure relates to dielectric films and techniques for forming dielectric films.

### BACKGROUND

Current demands for faster circuitry having greater circuit densities has driven to a great degree of current research and innovation into the materials and processes implemented in the fabrication of such integrated circuits. Guided by the current trend of reducing the size of the integrated circuits, it has become necessary to develop materials and fabrication processes that implement low dielectric materials and/or allow for the dielectric constant of such films to be reduced. However, current materials and processes utilized to reduce the dielectric constant of such films often result in poor mechanical properties and performance thereof.

Thus, a need remains for the development of dielectric film materials and new fabrication methods to produce thin, low dielectric films having improved mechanical properties.

### SUMMARY

The present disclosure relates to dielectric films and methods thereof.

In some embodiments, a method of forming a dielectric film includes exposing a substrate in a processing chamber to a silicon precursor having general Formula (I) to form a silicon-containing film on the substrate. Formula (I) can be represented by:

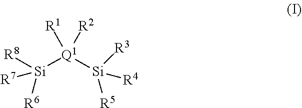

wherein Q¹ is a carbon atom or an oxygen atom, and each of R¹, R², R³, R⁴, R⁵, R⁶, R⁷, and R⁸ is independently selected from a hydrogen atom, a substituted alkyl, an unsubstituted alkyl, a substituted alkoxy, an unsubstituted alkoxy, a substituted vinyl, an unsubstituted vinyl, a silane, a substituted amine, an unsubstituted amine, or a halide. The method further includes purging the processing chamber of the silicon precursor.

In some embodiments, a method of preparing a dielectric film includes exposing a substrate in a processing chamber to a silicon precursor having general Formula (II) to form a silicon-containing film on the substrate. Formula (II) can be represented by:

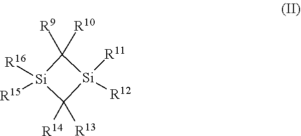

wherein Q² is a carbon atom or a silicon atom, and each of R⁹, R¹⁰, R¹¹, R¹², R¹³, R¹⁴, R¹⁵, and R¹⁶ is independently selected from a hydrogen atom, a substituted alkyl, an unsubstituted alkyl, a substituted alkoxy, an unsubstituted alkoxy, a substituted vinyl, an unsubstituted vinyl, a silane, a substituted amine, an unsubstituted amine, or a halide. The method further including purging the processing chamber of the silicon precursor.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a schematic cross-section view of a CVD process chamber configured according to one or more embodiments.

FIG. 2 depicts a flow diagram of a method according to one or more embodiments.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

The present disclosure provides techniques for producing dielectric films having a reduced dielectric constant (k) and increased Young's modulus (E) and hardness values (H). In various embodiments, such techniques implement, for example, principles of atomic scale structural design. In some embodiments disclosed herein, a film containing silicon, oxygen, and carbon is deposited on a surface of a substrate at conditions sufficient to form a low dielectric constant film. In at least one embodiment, the film may be deposited onto a substrate via any one or more methods known to one of ordinary skill in the art, such as physical vapor deposition (PVD), chemical vapor deposition (CVD), plasma enhanced chemical vapor deposition (PECVD), and the like. Such films may be processed further via one or more post-treatment methods know to one of ordinary skill in the art, such as chemical and mechanical polishing (CMP), plasma treatments and/or plasma etching, chemical cleaning, and the like. Notably, processes disclosed herein can produce low-k films having enhanced mechanical properties from SiOC precursors. In some embodiments, the low k film has a k value of about 3.5 or less, such as about 2.7 or less, such as between about 2.5 and 2.7. In some embodiments, the low k film has a Young's modulus of about 10 GPa to about 40 GPa. In some embodiments, the low k film has a hardness value of at least about 2.0 GPa, such as at least about 5.0 GPa, such as between about 4.0 GPa to about 6.0 GPa.

Before describing several exemplary embodiments of the disclosure, it is to be understood that the disclosure is not limited to the details of construction or process steps set forth in the following description. The disclosure is capable of other embodiments and of being practiced or being carried out in various ways.

Many of the details, dimensions, angles and other features shown in the Figures are merely illustrative of particular embodiments. Accordingly, other embodiments can have other details, components, dimensions, angles and features without departing from the spirit or scope of the present disclosure. In addition, further embodiments of the disclosure can be practiced without several of the details described below.

A “substrate,” “substrate surface,” or the like, as used herein, refers to any substrate or material surface formed on a substrate upon which processing is performed. For example, a substrate surface on which processing can be performed include, but are not limited to, materials such as silicon, silicon oxide, strained silicon, silicon on insulator (SOI), carbon doped silicon oxides, silicon nitride, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate (or otherwise generate or graft target chemical moieties to impart chemical functionality), anneal and/or bake the substrate surface. In addition to processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates. Thus, for example, where a film/layer or partial film/layer has been deposited onto a substrate surface, the exposed surface of the newly deposited film/layer becomes the substrate surface. What a given substrate surface comprises will depend on what materials are to be deposited, as well as the particular chemistry used.

As used in this specification and the appended claims, the terms “reactive compound,” “reactive gas,” “reactive species,” “precursor,” “process gas,” and the like are used interchangeably to mean a substance with a species capable of reacting with the substrate surface or material on the substrate surface in a surface reaction (e.g., chemisorption, oxidation, reduction). For example, a first “reactive gas” may simply adsorb onto the surface of a substrate and be available for further chemical reaction with a second reactive gas.

As used in this specification and the appended claims, the terms “precursor,” “reactant,” “reactive gas” and the like are used interchangeably to refer to any gaseous species that can react with the substrate surface.

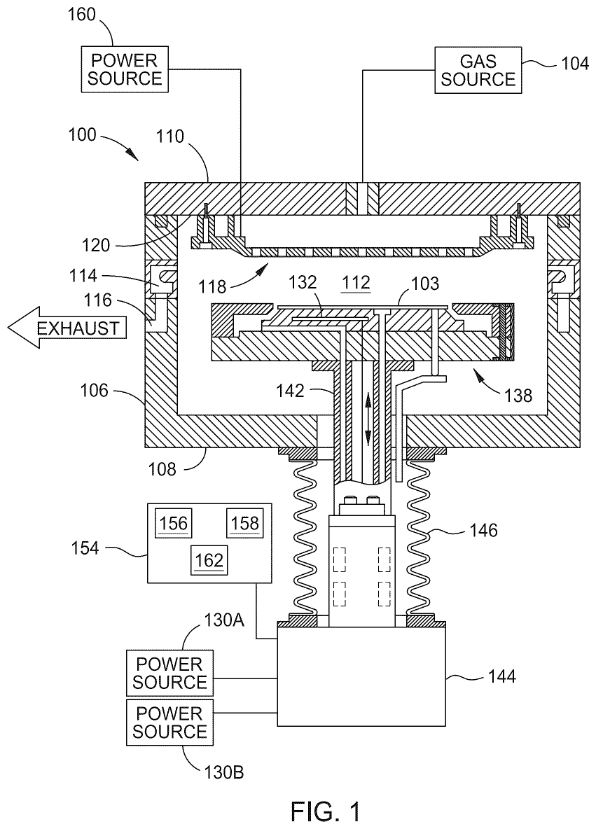

FIG. 1 is a schematic cross-sectional view of a process chamber 100, such as a CVD process chamber, that may be used for depositing a silicon based layer according to the embodiments described herein. A process chamber 100 is available from Applied Materials, Inc. located in Santa Clara, Calif., and a brief description thereof follows. Processing chambers that may be adapted to perform the carbon layer deposition methods described herein is the PRODUCER® chemical vapor deposition chamber, both available from Applied Materials, Inc. located in Santa Clara, Calif. It is to be understood that the chamber described below is an exemplary embodiment and other chambers, including chambers from other manufacturers, may be used with or modified to match embodiments described herein without diverging from the inventive characteristics described herein.

The process chamber 100 may be part of a processing system (not shown) that includes multiple processing chambers connected to a central transfer chamber (not shown) and serviced by a robot (not shown). The process chamber 100 includes walls 106, a bottom 108, and a lid 110 that define a process volume 112. The walls 106 and bottom 108 can be fabricated from a unitary block of aluminum. The process chamber 100 may also include a pumping ring 114 that fluidly couples the process volume 112 to an exhaust port 116 as well as other pumping components (not shown).

A substrate support assembly 138, which may be heated, may be centrally disposed within the process chamber 100. The substrate support assembly 138 supports a substrate 103 during a deposition process. The substrate support assembly 138 generally is fabricated from aluminum, ceramic or a combination of aluminum and ceramic, and includes at least one bias electrode 132.

A vacuum port may be used to apply a vacuum between the substrate 103 and the substrate support assembly 138 to secure the substrate 103 to the substrate support assembly 138 during the deposition process. The bias electrode 132, may be, for example, the bias electrode 132 disposed in the substrate support assembly 138, and coupled to a bias power source 130A and 130B, to bias the substrate support assembly 138 and substrate 103 positioned thereon to a predetermined bias power level while processing.

The bias power source 130A and 130B can be independently configured to deliver power to the substrate 103 and the substrate support assembly 138 at a variety of frequencies, such as a frequency between about 1 MHz and about 60 MHz. In one embodiment, the bias power source 130A may be configured to deliver power to the substrate 103 at a frequency of about 2 MHz and the bias power source 130B may be configured to deliver power to the substrate 103 at a frequency of about 13.56 MHz. In another embodiment, the bias power source 130A may be configured to deliver power to the substrate 103 at a frequency of 2 MHz, the bias power source 130B may be configured to deliver power to the substrate 103 at a frequency of 13.56 MHz and a third power source (not shown) is configured to deliver power to the substrate 103 at a frequency of about 60 MHz. Various permutations of the frequencies described here can be employed without diverging from the embodiments described herein.

Generally, the substrate support assembly 138 is coupled to a stem 142. The stem 142 provides a conduit for electrical leads, vacuum and gas supply lines between the substrate support assembly 138 and other components of the process chamber 100. Additionally, the stem 142 couples the substrate support assembly 138 to a lift system 144 that moves the substrate support assembly 138 between an elevated position (as shown in FIG. 1) and a lowered position (not shown) to facilitate robotic transfer. Bellows 146 provide a vacuum seal between the process volume 112 and the atmosphere outside the process chamber 100 while facilitating the movement of the substrate support assembly 138.

The showerhead 118 may generally be coupled to an interior side 120 of the lid 110. Gases (e.g., process and other gases) that enter the process chamber 100 from a gas source 104 pass through the showerhead 118 and into the process chamber 100. The showerhead 118 may be configured to provide a uniform flow of gases to the process chamber 100. Uniform gas flow is desirable to promote uniform layer formation on the substrate 103. A plasma power source 160 may be coupled to the showerhead 118 to energize the gases through the showerhead 118 towards substrate 103 disposed on the substrate support assembly 138. The plasma power source 160 may provide RF power. Further, the plasma power source 160 can be configured to deliver power to the showerhead 118 at a variety of frequencies, such as a frequency between about 100 KHz and about 40 MHz. In one embodiment, the plasma power source 160 is configured to deliver power to the showerhead 118 at a frequency of 13.56 MHz.

The function of the process chamber 100 can be controlled by a computing device 154. The computing device 154 may be one of any form of general purpose computer that can be used in an industrial setting for controlling various chambers and sub-processors. The computing device 154 includes a computer processor 156. The computing device 154 includes memory 158. The memory 158 may include any suitable memory, such as random access memory, read only memory, flash memory, hard disk, or any other form of digital storage, local or remote. The computing device 154 may include various support circuits 162, which may be coupled to the computer processor 156 for supporting the computer processor 156 in a conventional manner. Software routines, as required, may be stored in the memory or executed by a second computing device (not shown) that is remotely located.

The computing device 154 may further include one or more computer readable media (not shown). Computer readable media generally includes any device, located either locally or remotely, which is capable of storing information that is retrievable by a computing device. Examples of computer readable media useable with embodiments of the present embodiments include solid state memory, floppy disks, internal or external hard drives, and optical memory (CDs, DVDs, BR-D, etc). In one embodiment, the memory 158 may be the computer readable media. Software routines may be stored on the computer readable media to be executed by the computing device.

The software routines, when executed, transform the general purpose computer into a specific process computer that controls the chamber operation so that a chamber process is performed. Alternatively, the software routines may be performed in hardware as an application specific integrated circuit or other type of hardware implementation, or a combination of software and hardware.

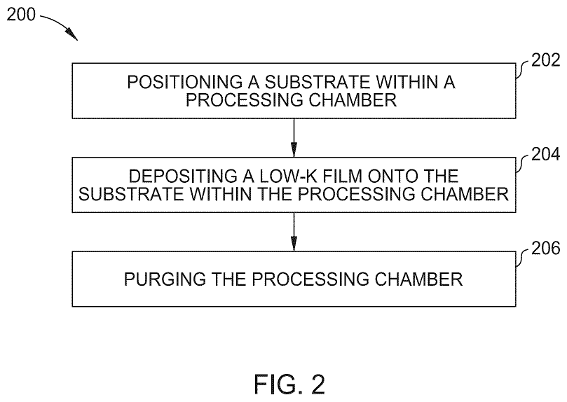

FIG. 2 depicts a flow diagram showing selected operations of a method 200 for preparing low-k films deposited onto a substrate. At operation 202, a substrate may be introduced to a process chamber (e.g., process chamber 100) and positioned on a substrate support capable of performing PECVD. At operation 204, a low-k film may be deposited onto a substrate from one or more precursors introduced into the processing chamber via any one or more methods known to one of ordinary skill in the art (e.g., PECVD). At operation 206, the process chamber is purged of the one or more precursors to provide a low-k film deposited over a substrate.

At operation 204, a low-k film may be deposited onto a substrate via any of one or more methods known to one of ordinary skill in the art to form a preprocessed substrate, where one or more organosilicon compounds are introduced to the processing chamber (e.g., process chamber 100). The deposition process may include one or more of chemical vapor deposition (CVD), physical vapor deposition (PVD), atomic layer deposition (ALD), PECVD, or a combination thereof. Further, at least one of the organosilicon compounds includes a silicon atom bound to either a carbon atom and/or an oxygen atom. An inert carrier gas, such as a noble gas (e.g., argon or helium) may be introduced to the processing chamber with the one or more organosilicon compounds. In some embodiments, an oxidizing gas may be additionally introduced into the processing chamber. The one or more organosilicon compounds and, optionally, the oxidizing gas, are reacted in the presence of RF power to deposit a low-k film on the substrate in the processing chamber. The deposited low-k film may then be post-treated with an ultra-violet radiation curing process to induce crosslinking of the film, increasing the mechanical properties thereof.

In some embodiments, at least one of the one or more organosilicon compounds includes a silicon-containing component, wherein a silicon atom bonded to at least one of a carbon atom and/or an oxygen atom. In at least one embodiment, the silicon containing component may include any one or more silicon based compound, such as trimethylsilane, triethoxysilane, methyldiethoxysilane, dimethylethoxysilane, dimethylmethoxysilane, methyldimethoxysilane, dimethyldisiloxane, tetramethyldisiloxane, 1,3-bis(silanomethylene)disiloxane, bis(1-methyldisiloxanyl)methane, bis(1-methyldisiloxanyl)propane, and combinations thereof.

In some embodiments, the one or more organosilicon compounds may include, for example, dimethyldimethoxysilane (DMDMOS), methyldiethoxysilane (MDEOS), trimethylsilane (TMS), triethoxysilane, dimethylethoxysilane, dimethyldisiloxane, tetramethyldisiloxane, hexamethyldisiloxane (HMDS), 1,3-bis(silanomethylene)disiloxane, bis(1-methyldisiloxanyl)methane, bis(1-methyldisiloxanyl)propane, hexamethoxydisiloxane (HMDOS), dimethoxymethylvinylsilane (DMMVS), and combinations thereof. In some embodiments, the one or more organosilicon compounds may include one or more cyclic compounds, such as tetramethylcyclotetrasiloxane (TMCTS), octamethylcyclotetrasiloxane (OMCTS), pentamethylcyclopentasiloxane, hexamethylcyclotrisiloxane, and combinations thereof.

In some embodiments, the one or more organosilicon compounds may include one or more compounds which can be represented by Formula (I):

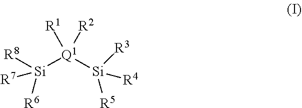

wherein Q¹ is either a carbon atom or an oxygen atom, and each of R¹, R², R³, R⁴, R⁵, R⁶, R⁷, and R⁸ is independently selected from a hydrogen atom, a substituted alkyl, an unsubstituted alkyl, a substituted alkoxy, an unsubstituted alkoxy, a substituted vinyl, an unsubstituted vinyl, a silane, a substituted amine, an unsubstituted amine, or a halide. In at least one embodiment, at least one of R¹, R², R³, R⁴, R⁵, R⁶, R⁷, and R⁸ is a dimethylamine group, wherein the linkage to the compound of Formula (I) occurs through the nitrogen atom.

In some embodiments, the one or more organosilicon compounds may include one or more compounds which can be represented by Formula (II):

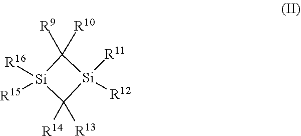

wherein Q² is either a carbon atom or a silicon atom, and each of R⁹, R¹⁰, R¹¹, R¹², R¹³, R¹⁴, R¹⁵, and R¹⁶ is independently selected from a hydrogen atom, a substituted alkyl, an unsubstituted alkyl, a substituted alkoxy, an unsubstituted alkoxy, a substituted vinyl, an unsubstituted vinyl, a silane, a substituted amine, an unsubstituted amine, or a halide. In at least one embodiment, at least one of R⁹, R¹⁰, R¹¹, R¹², R¹³, R¹⁴, R¹⁵, and R¹⁶ is a dimethylamine group, wherein the linkage to the compound of Formula (II) occurs through the nitrogen atom.

In some embodiments, the one or more organosilicon compounds may include one or more of 1,1-Bis(dimethylamino)-3,3-bis(dimethylamino)siletane, 1,3-Bis(dimethylamino)-1,3-divinyl-1,3-disiletane, 1,3-Bis(dimethylamino)-1,3-dimethyl-1,3-disiletane, 1,1,3,3-Tetrakis(dimethylamino)-1,3-disiletane, 1,3-Bis(dimethylamino)-1,3-divinyl-1,3-disiletane, Bis(trisdimethylamino)silyl methane, and the like.

In some embodiments, the one or more organosilicon compounds may include one or more of octamethylcyclotetrasiloxane, 2,4,6,8-tetramethyl-2,4,6,8-tetravinylcyclotetrasiloxane, 2,4,6,8-tetramethylcyclotetrasiloxane, dimethyldimethoxysilane, ethoxydimethylsilane, isobutylmethyldimethoxysilane, vinylmethyldimethoxysilane, 1,1,3,3-tetramethyl-1,3-dimethoxydisiloxane, 1,3-dimethyl-1, 1,3,3-tetramethoxydisiloxane, methoxy(dimethyl)silylmethane, methyl(dimethoxy)silylmethane, bis(trimethylsilyl)methane, 1,3-diethoxy-1,3-dimethyl-1,3-disilacyclobutane, and 1,3-dimethyl-1,3-diphenyl-1,3-disilacyclobutane.

In some embodiments, the oxidizing gases are oxygen containing compounds selected from the group of oxygen (O₂), nitrous oxide (N₂O), ozone (O₃), water (H₂O), carbon dioxide (CO₂), carbon monoxide (CO), and combinations thereof.

At operation 204, the one or more organosilicon compounds, and optionally, the oxidizing gas and any inert gases, are reacted in the presence of RF power to deposit a low k film on a substrate in the chamber. In some embodiments, the one or more organosilicon compounds implemented in the formation of the low k film include at least one compound that is represented by Formula (I) and/or Formula (II). For example, the one or more organosilane compounds may include a first compound and a second compound, wherein the first compound can be represented by either Formula (I) or Formula (II), and the second compound can be any organosilicon compound different from the first compound. Interestingly, it has been found that incorporating at least one compound represented by Formula (I) and/or Formula (II) can increase the mechanical performance of the produced low k film. Without being bound by theory, it is postulated that including a compound represented by Formula (I) and/or Formula (II) can increase the total amount of Si—C—Si in the resulting films, thereby improving the mechanical properties of the resulting films. Such improvements in mechanical properties can be beneficial in maintaining inherent film properties throughout various post-deposition processing procedures (e.g., curing and etching).

In various embodiments, a substrate is positioned on a substrate support in a processing chamber capable of performing PECVD (e.g., operation 202). A gas mixture having a composition including one or more organosilicon compounds, and optionally the oxidizing gas, is introduced into the chamber through a gas distribution plate of the chamber, such as a showerhead. A RF power is applied to an electrode, such as the showerhead, in order to provide plasma processing conditions in the chamber. The gas mixture is reacted in the chamber in the presence of RF power to deposit a low-k film comprising a silicon oxide layer that adheres strongly to the underlying substrate (e.g., operation 204). The low-k film may be post-treated via one or more curing processes (e.g., UV curing processes) to further harden the deposited film.

The RF source may comprise a high frequency radio frequency (HFRF) power source, such as a 13.56 MHz RF generator, and a low frequency radio frequency (LFRF) power source, such as a 200 kHz RF generator. The LFRF power source provides both low frequency generation and fixed match elements. The HFRF power source is designed for use with a fixed match and regulates the power delivered to the load, eliminating concerns about forward and reflected power.

During the reaction of the one or more organosilicon compounds and the oxidizing gas to deposit the low dielectric constant layer on the substrate in the chamber, the substrate is typically maintained at a temperature between about 100° C. and about 450° C. The chamber pressure may be between about 0.5 Torr and about 500 Torr, such as between about 5 Torr and about 150 Torr and the spacing between a substrate support and the chamber showerhead may be between about 100 mils and about 1500 mils, such as between about 200 mils and about 1000 mils.

The one or more organosilicon compounds may be introduced into the chamber at a flow rate from about 50 mg/minute to about 5000 mg/minute, such as at a flow rate from about 100 mg/minute to about 3000 mg/minute. The optional oxidizing gas (e.g., O₂) may be introduced into the chamber at a flow rate from about 0 sccm and about 1000 sccm, such as at a flow rate from about 0 sccm to about 500 sccm. A dilution or carrier gas, such as helium, argon, or nitrogen, may also be introduced into the chamber at a flow rate between about 10 sccm and about 10000 sccm, such as at a flow rate from about 50 sccm to about 5000 sccm.

The plasma may be generated by applying a power density ranging between about 0.2 W/cm² and about 2.8 W/cm², which is a RF power level of between about 10 W and about 2000 W, such as 0.03 W/cm² and about 1.4 W/cm², which is a RF power level of between about 50 W and about 1000 W for a 300 mm substrate, may be used. The RF power is provided at a frequency between about 200 kHz and 40 MHz, such as about 13.56 MHz. The RF power may be provided at a mixed frequency, such as at a high frequency of about 13.56 MHz and a low frequency of about 350 kHz. The RF power may be cycled or pulsed to reduce heating of the substrate. The RF power may also be continuous or discontinuous.

A “pulse” or “dose” as used herein is intended to refer to a quantity of a source gas that is intermittently or noncontinuously introduced into the process chamber. The quantity of a particular compound within each pulse may vary over time, depending on the duration of the pulse. The durations for each pulse/dose are variable and may be adjusted to accommodate, for example, the volume capacity of the processing chamber as well as the capabilities of a vacuum system coupled thereto. Additionally, the dose time of a process gas may vary according to the flow rate of the process gas, the temperature of the process gas, the type of control valve, the type of process chamber employed, as well as the ability of the components of the process gas to adsorb onto the substrate surface. Dose times may also vary based upon the type of layer being formed and the geometry of the device being formed. A dose time should be long enough to provide a volume of compound sufficient to adsorb/chemisorb onto substantially the entire surface of the substrate and form a layer of a process gas component thereon.

In some embodiments, the resulting low-k films deposited onto the substrate have a thickness of greater than about 500 Å. In some embodiments, the resulting low k films deposited onto the substrate have a thickness of about 1000 Å to about 4000 Å.

After the low k film is deposited, the processing chamber is purged of the organosilicon containing gas mixture (e.g., operation 206). In some embodiments, the layer may be post-treated. In one embodiment, the low k film is cured by application of UV radiation. The UV radiation application may be used in conjunction, concurrently or serially, with additional post-treatments, such as electron beam (e-beam) treatments, plasma-based treatments, thermal annealing treatments, and combinations thereof, among others.

An example of UV post-treatment conditions that may be used include a chamber pressure of between about 5 Torr and about 50 Torr, such as from 6 Torr to 20 Torr, and a substrate support temperature from about 50° C. to about 600° C., such as from about 100° C. to about 500° C. The UV radiation may be provided by any UV source, such as mercury microwave arc lamps, pulsed xenon flash lamps, or high efficiency UV light emitting diode arrays. The UV radiation may have a wavelength of between about 170 nm and about 500 nm, for example. Helium gas may be supplied at a flow rate of between about 100 sccm and 30,000 sccm. In certain embodiments, gases such as helium, argon, nitrogen gas, hydrogen gas, and oxygen gas, or any combination thereof may be used. The UV power may be between about 40% and about 100% and the processing time may be between about 0 minutes and about 20 minutes.

Further details of UV chambers and treatment conditions that may be used are described in commonly assigned U.S. patent application Ser. No. 11/124,908, filed on May 9, 2005, which is incorporated by reference herein. The NanoCure™ chamber from Applied Materials, Inc., is an example of a commercially available chamber that may be used for UV post-treatments.

An exemplary thermal annealing post-treatment includes annealing the layer at a substrate temperature between about 50° C. and about 500° C. for about 2 seconds to about 3 hours, preferably about 0.5 hours to about 2 hours, in a chamber. A non-reactive gas (e.g., helium, hydrogen, nitrogen, or a mixture thereof) and/or a reactive gas (e.g., oxygen, ammonia, or a mixture thereof) may be introduced into the chamber at a rate of about 20 sccm to about 10,000 sccm. The chamber pressure is maintained between about 1 m Torr and about 40 Torr. The preferred substrate spacing is between about 100 mils and about 1200 mils.

In some embodiments, the thermal annealing post-treatment includes annealing the layer at a substrate temperature in the range of about 200° C. to about 400° C., alternatively about 500° C. to about 1000° C.,. The annealing environment of some embodiments comprises one or more of an inert gas (e.g., molecular nitrogen (N₂) and/or argon (Ar)), a reducing gas (e.g., molecular hydrogen (H₂) and/or ammonia (NH₃)) or an oxidant, (e.g., oxygen (O₂), ozone (O₃), and/or peroxides). Annealing can be performed for any suitable length of time. In some embodiments, the film is annealed for a predetermined time in the range of about 15 seconds to about 90 minutes. In some embodiments, annealing the as deposited film increases the density, decreases the resistivity and/or increases the purity of the film.

In some embodiments, the deposited low-k film of the processed substrate, may be subjected to a plasma treatment to form a modified layer on the surface of the low-k film. The plasma treatment may be performed in the same chamber used to deposit the one or more organosilicon compounds. The plasma treatment may include providing an inert gas (e.g., helium, argon, neon, xenon, krypton, or combinations thereof) and/or a reducing gas (e.g., hydrogen, ammonia, and combinations thereof) to a processing chamber. The plasma treatment may be performed between about 10 seconds and about 900 seconds.

Without being bound by theory, the plasma treatment is believed to clean contaminants from the exposed surface of the low k dielectric film and may be used to stabilize the layer, or at least produce a modified layer thereon, such that it becomes less reactive with moisture and/or oxygen under atmospheric conditions as well as the adhesion of layers formed thereon.

However, it should be noted that the respective parameters might be modified to perform the plasma processes in various chambers and for different substrate sizes, such as 300 mm substrates. An example of a plasma treatment for a silicon and carbon containing film is further disclosed in U.S. patent application Ser. No. 09/336,525, entitled, “Plasma Treatment to Enhance Adhesion and to Minimize Oxidation of Carbon-Containing Layers,” filed on Jun. 18, 1999, which is incorporated herein by reference to the extent not inconsistent with the disclosure and claimed aspects of the invention described herein.

In some embodiments, the one or more plasma treatment processes include providing the treatment gas (e.g., NH₃) to the processing chamber at a flow rate of about 10 mg/minute to about 3000 mg/minute, such as about 10 mg/minute to about 1500 mg/minute, alternatively about 1500 mg/minute to about 3000 mg/minute. In one or more embodiments, an inert carrier gas is also provided to the process chamber at a flow rate of about 50 sccm to about 5000 sccm to provide a uniform etch profile, such as about 50 sccm to about 2500 sccm, alternatively about 2500 sccm to about 5000 sccm. The plasma may be generated by applying a RF power of about 10 W to about 1000 W to the processing chamber, such as about 10 W to about 200 W, such as about 50 W to about 200 W. In some embodiments, a bias power of about 0 W to about 300 W may be applied to the processing chamber. The RF power may be provided at a mixed frequency, such as at a high frequency of about 13.56 MHz and a low frequency of about 200 kHz. The RF power may be cycled or pulsed to reduce heating of the substrate. The RF power may also be continuous or discontinuous. In some embodiments, the RF power used to generate the plasma is applied to the processing chamber via pulsing at a frequency of about 200 kHz to about 40 MHz.

The pressure of the processing chamber is maintained at about 0.5 Torr to about 500 Torr throughout at least one of the plasma treatment processes, such as about 1 Torr to about 250 Torr, such as about 5 Torr to about 150 Torr. The temperature within the processing chamber is maintained at about 100° C. to about 450° C. throughout at least one of the plasma treatment processes, such as about 150° C. to about 400° C., such as about 200° C. to about 350° C.

In some embodiments, the one or more plasma treatments may etch the surface of the low k dielectric film at a rate of less than about 160 Å/min, such as less than about 100 Å/min, such as less than about 50 Å/min. In some embodiments the one or more plasma treatments may etch the surface of the low k dielectric film at a rate of about 160 Å/min to about 10 Å/min,.

In some embodiments, it may be desirable to conduct a chemical cleaning process to the surface of a plasma treated low k film (e.g., the modified layer) to remove oxidized and/or unoxidized portions therefrom. For instance, substrates having such plasma treated low k films deposited thereon may be immersed in one or more cleaning solutions comprising a component that breaks Si—O to remove low k dielectric residues from the surface of such films, such as the modified layer produced from the one or more plasma treatment processes.

The modified layer may be removed from the modified substrate via a chemical cleaning process applied to the surface of the plasma treated low-k film (e.g., the modified layer) to produce a processed substrate having a processed low-k film. In some embodiments, the one or more cleaning solutions can include an aqueous solution of NH₄F, HF, or a combination thereof. In at least one embodiment, the cleaning solution is a dilute HF solution having a concentration of about 0.1 wt % to about 10 wt % of HF, such as about 0.1 wt % to about 5 wt %, alternatvely about 5 wt % to about 10 wt %. The substrate may be immersed in the one or more cleaning solutions, such that the low k dielectric residues resulting from the one or more plasma treatment processes are substantially removed from the surface of the low k film.

In some embodiments, the treated and cleaned low k films have a thickness of less than about 800 Å, such as less than about 950 Å. In some embodiments, the treated and cleaned low k films have a thickness ranging from about 80 Å to about 3500 Å. In some embodiments, the treated and cleaned low k films have a dielectric constant value of less than about 3.85, such as less than about 2.9, such as less than about 2.6. In some embodiment, the treated and cleaned low k films have a dielectric constant value ranging from about 2.52 to about 3.85, such as about 2.52 to about 2.9, such as about 2.6 to about 2.9.

Low k dielectric films of the present disclosure are intentionally formulated using organosilicon precursors having “built-in” Si—C—Si bonds. As such, the total Si—C—Si content present in the treated and cleaned low k films is expected to be higher relative to films formed from traditional linear precursors. Interestingly, it has been found that films formed from methods and organosilicon compounds disclosed herein exhibit improved mechanical properties over films formed from traditional linear precursors, without detriment to the dielectric constant value. Without being bound by theory, increasing the total amount of Si—C—Si in the resulting films can improve the mechanical properties of the resulting therefrom. In some embodiments, the treated and cleaned films of the present disclosure have about 0.05% to about 0.93% of Si—C—Si bonds, such as about 0.05% to about 0.7%, such as about 0.15% to about 0.6%, such as about 0.35% to about 0.55%, as determined by Fourier Transform Infrared (FTIR) spectroscopy. Furthermore, it was found that when plasma treated using a pulsed RF power source, the resulting cleaned and treated films contained about 5% to about 40% less Si—C—Si bonds than those plasma treated using a continuous RF power source, such as about 10% to about 35% more Si—C—Si bonds, such as about 15% to about 30% more Si—C—Si bonds.

In some embodiments, the treated and cleaned films of the present disclosure have a hardness value of about 2.12 GPa to about 9.16 GPa as determined using a Nano Indenter G200 system produced by Agilent Technologies, such as about 3.0 GPa to about 7.5 GPa, such as about 4.0 GPa to about 6.0 GPa. In some embodiments, the treated and cleaned films of the present disclosure have a Young's modulus of about 8 GPa to about 50 GPa as using a Nano Indenter G200 system produced by Agilent Technologies, such as about 10 GPa to about 40 GPa, such as about 20 GPa to about 30 GPa.

Overall, the present disclosure provides methods of preparing thin, low dielectric constant films from various organosilicon precursors. In particular, dielectric films of the present disclosure were formulated from organosilicon precursor compounds having “built-in” Si—C—Si bonds. It was found that films formed from methods and organosilicon compounds disclosed herein exhibit improved mechanical properties over films formed from traditional linear precursors using similar processing and fabrication methods, without detriment to the dielectric constant value. As such, it was determined that increasing the total amount of Si—C—Si in the resulting films can improve the mechanical properties of the resulting therefrom.

The phrases, unless otherwise specified, “consists essentially of” and “consisting essentially of” do not exclude the presence of other steps, elements, or materials, whether or not, specifically mentioned in this specification, so long as such steps, elements, or materials, do not affect the basic and novel characteristics of the present disclosure, additionally, they do not exclude impurities and variances normally associated with the elements and materials used.

Numerical ranges used herein include the numbers recited in the range. For example, the numerical range “from 1 wt % to 10 wt %” includes 1 wt % and 10 wt % within the recited range.

For the sake of brevity, only certain ranges are explicitly disclosed herein. However, ranges from any lower limit may be combined with any upper limit to recite a range not explicitly recited, as well as, ranges from any lower limit may be combined with any other lower limit to recite a range not explicitly recited, in the same way, ranges from any upper limit may be combined with any other upper limit to recite a range not explicitly recited. Additionally, within a range includes every point or individual value between its end points even though not explicitly recited. Thus, every point or individual value may serve as its own lower or upper limit combined with any other point or individual value or any other lower or upper limit, to recite a range not explicitly recited.

All numerical values within the detailed description herein are modified by “about” the indicated value, and take into account experimental error and variations that would be expected by a person having ordinary skill in the art.

All documents described herein are incorporated by reference herein, including any priority documents and or testing procedures to the extent they are not inconsistent with this text. As is apparent from the foregoing general description and the specific embodiments, while forms of the present disclosure have been illustrated and described, various modifications can be made without departing from the spirit and scope of the present disclosure. Accordingly, it is not intended that the present disclosure be limited thereby. Likewise, the term “comprising” is considered synonymous with the term “including” for purposes of United States law. Likewise whenever a composition, an element or a group of elements is preceded with the transitional phrase “comprising,” it is understood that we also contemplate the same composition or group of elements with transitional phrases “consisting essentially of,” “consisting of,” “selected from the group of consisting of,” or “is” preceding the recitation of the composition, element, or elements and vice versa.

While the present disclosure has been described with respect to a number of embodiments and examples, those skilled in the art, having benefit of this disclosure, will appreciate that other embodiments can be devised which do not depart from the scope and spirit of the present disclosure.

What is claimed is:

1. A method of forming a dielectric film, the method comprising:
exposing a substrate in a processing chamber to a silicon precursor having general Formula (I) to form a silicon-containing film on the substrate, Formula (I) being represented by: 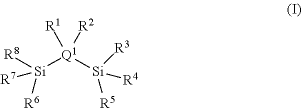
wherein:
Q¹ is a carbon atom or an oxygen atom; and
each of R¹, R², R³, R⁴, R⁵, R⁶, R⁷, and R⁸ is independently selected from a hydrogen atom, a substituted alkyl, an unsubstituted alkyl, a substituted alkoxy, an unsubstituted alkoxy, a substituted vinyl, an unsubstituted vinyl, a silane, a substituted amine, an unsubstituted amine, or a halide; and
purging the processing chamber of the silicon precursor.

2. The method of claim 1, wherein Q¹ is a carbon atom.

3. The method of claim 1, wherein exposing the substrate in the processing chamber to deposit the silicon-containing film further comprises providing a radio frequency (RF) power to the processing chamber to generate a plasma.

4. The method of claim 3, wherein the RF power provided to the processing chamber is from about 10 W to about 1000 W at a frequency of about 200 kHz to about 40 MHz.

5. The method of claim 1, wherein the silicon-containing film comprises about 0.05% to about 0.93% of Si—C—Si bonds.

6. The method of claim 1, wherein the silicon-containing film comprises about 0.35% to about 0.55% of Si—C—Si bonds.

7. The method of claim 1, wherein the processing chamber is maintained at a pressure of about 0.5 Torr to about 500 Torr.

8. The method of claim 1, wherein the silicon precursor is introduced into the processing chamber at a flow rate of about 10 mg/minute to about 3000 mg/min.

9. The method of claim 1, wherein an oxidizing gas is further introduced to the processing chamber, the oxidizing gas being introduced to the processing chamber at a gas flow rate of less than about 1000 sccm.

10. The method of claim 1, wherein the silicon-containing film comprises:
a thickness of about 800 Å to about 3500 Å;
a dielectric constant of about 2.52 to about 3.85; and
a hardness value of about 2.12 GPa to about 9.16 GPa.

11. A method of preparing a dielectric film, the method comprising:
exposing a substrate in a processing chamber to a silicon precursor having general Formula (II) to form a silicon-containing film on the substrate, Formula (II) being represented by: 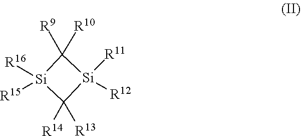
wherein:
each of R⁹, R¹⁰, R¹¹, R¹², R¹³, R¹⁴, R¹⁵, and R¹⁶ is independently selected from a hydrogen atom, a substituted alkyl, an unsubstituted alkyl, a substituted alkoxy, an unsubstituted alkoxy, a substituted vinyl, an unsubstituted vinyl, a silane, a substituted amine, an unsubstituted amine, or a halide; and
purging the processing chamber of the silicon precursor.

12. The method of claim 11, wherein the silicon-containing film comprises:
a thickness of about 800 Å to about 3500 Å;
a dielectric constant of about 2.52 to about 3.85;
a hardness value of about 2.12 GPa to about 9.16 GPa; and
about 0.05% to about 0.7% of Si—C—Si bonds.

13. The method of claim 11, wherein exposing the substrate in the processing chamber to deposit the silicon-containing film further comprises providing a radio frequency (RF) power to the processing chamber to generate a plasma.

14. The method of claim 13, wherein the RF power provided to the processing chamber is from about 10 W to about 1000 W at a frequency of about 200 kHz to about 40 MHz.

15. The method of claim 11, wherein the silicon-containing film comprises about 0.05% to about 0.93% of Si—C—Si bonds.

16. The method of claim 11, wherein the silicon-containing film comprises about 0.35% to about 0.55% of Si—C—Si bonds.

17. The method of claim 11, wherein the processing chamber is maintained at a pressure of about 0.5 Torr to about 500 Torr.

18. The method of claim 11, wherein the silicon precursor is introduced into the processing chamber at a flow rate of about 10 mg/minute to about 3000 mg/min.

19. The method of claim 11, wherein an oxidizing gas is further introduced to the processing chamber, the oxidizing gas being introduced to the processing chamber at a gas flow rate of less than about 1000 sccm.

20. The method of claim 11, wherein the silicon-containing film comprises:
a thickness of about 800 Å to about 3500 Å;
a dielectric constant of about 2.52 to about 3.85; and
a hardness value of about 2.12 GPa to about 9.16 GPa.
